(19) United States
(12) Patent Application Publication
(10) Pub. No.: US 2002/0008294 A1
(43) Pub. Date: Jan. 24, 2002

(54) Semiconductor device and method for manufacturing same

(75) Inventors: Kiyoshi Hayashi, Tokyo (JP); Yasuo Inoue, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, TOKYO (JP)

(21) Appl. No.: 09/749,901

(22) Filed: Dec. 29, 2000

(30) Foreign Application Priority Data
Jul. 21, 2000 (JP) P2000-220770

(51) Int. Cl. H01L 29/94; H01L 31/062

(52) U.S. Cl. 257/413; 257/412

(57) ABSTRACT

Provided are a semiconductor device comprising a polymetal gate electrode that can prevent formation of a silicide layer at the interface between metal and conductive silicon and also exhibit low resistance property and ohmic property, and a method for manufacturing the same. Specifically, a polymetal gate electrode is formed via a gate insulating film (2), e.g., an oxide film, on a semiconductor substrate (1), e.g., a silicon substrate. The polymetal gate electrode has such a structure that a conductive silicon film (3), e.g., a poly-Si film, a silicide film (4), e.g., a WSi film, a barrier film (5), e.g., a WSiN film, and a metal film (6), e.g., a W film, are stacked over the semiconductor substrate (1) in the order named.

### BACKGROUND OF THE INVENTION

1. Field of the Invention

The present invention relates generally to a semiconductor device and a method for manufacturing the same, and more specifically, to a gate electrode structure and a wiring structure having the same shape as a gate electrode of MISFETs (metal insulator semiconductor field effect transistors).

2. Description of the Background Art

Either of conductive silicon single layer structure (e.g., poly-Si) and silicide/conductive silicon stacked structure (e.g., WSi₂/poly-Si and CoSi₂/poly-Si) has mainly been adopted for a conventional gate electrode and wiring.

However, in situations where MISFETs and wirings are miniaturized as high integration of semiconductor integrated circuits proceeds, if the above-mentioned structures remain unchanged, the resistance value of a gate electrode and wiring is increased. The result is that the amount of signal delay in the gate electrode and wiring is increased, thereby diminishing the merit of high speed operation owing to miniaturization.

For instance, in case of CoSi₂/poly-Si stacked structure, the sheet resistance of CoSi₂ is relatively low, namely about 7 Ω, which in some cases may not be so large demerit over signal delay. However, since the CoSi₂/poly-Si stacked structure is formed by salicide (self aligned silicide) method, it is difficult to form a SAC (self aligned contact) structure while employing the CoSi₂/poly-Si stacked structure.

As used herein, the term “SAC structure” indicates the structure in which an insulting film such as a silicon nitride film is formed on the upper and side surfaces of a gate electrode and wiring. This insulating film functions to prevent the gate electrode and contact holes from being short-circuited even if alignment deviates when contact holes toward source/drain regions are formed in an interlayer insulating film. As high integration is advanced, the margin of the distance between the gate electrode and the contact holes toward the source/drain regions is reduced and thus liable to cause short-circuit. Hence, the SAC structure is becoming increasingly essential to high integrated semiconductor devices.

Since in salicide method a gate electrode and source/drain regions are simultaneously subjected to silicidation, an insulating film of SAC structure cannot be formed prior to salicide method. Therefore, the insulating film of SAC structure should be formed after passing through the process with salicide method.

In this state, it is however difficult to form an insulating film on the upper and side surfaces of the gate electrode. If an insulating film is formed by using photolithography and etching techniques, in some cases, alignment of the insulating film itself may deviate and fail to prevent short-circuit between the gate electrode and contact holes. For this reason, it is difficult to form the SAC structure while employing the CoSi₂/poly-Si stacked structure.

It can also be considered to form the CoSi₂/poly-Si stacked structure by polycide method in place of salicide method. However, the CoSi₂/poly-Si stacked structure cannot be formed by polycide method because any suitable method for removing the non-reacted Co remaining after formation of CoSi₂ has not presently been discovered.

As a gate electrode structure and a wiring structure, there has been proposed a polymetal gate electrode having a metal/barrier film/conductive silicon stacked structure that can further reduce sheet resistance than the conductive silicon single layer structure or silicide/conductive silicon stacked structure and also can form the SAC structure. Such gate electrode structure and wiring structure are introduced in, e.g., “A Novel 0.15 μm CMOS Technology using W/WNₓ/Polysilicon Gate Electrode and Ti Silicided Source/Drain Diffusions” IEDM '96, pp. 455-458, and “Formation mechanism of ultrathin WSiN barrier layer in a W/WNₓ/Si system” Applied Surface Science 117/118 (1997), pp. 312-316.

FIG. 12 illustrates a polymetal gate electrode structure. In FIG. 12, a polymetal gate electrode is formed via a gate insulating film 2 (e.g., oxide film) on a semiconductor substrate 1 (e.g., silicon substrate). The polymetal gate electrode has such a structure that a conductive silicon film 3 (e.g., poly-Si film), a barrier film 5 (e.g., WNₓ film or WSiN film) and a metal film 6 (e.g., W film) are stacked over the semiconductor substrate 1 in the order named.

In the polymetal gate electrode, sheet resistance is extremely small, namely about 5 Ω or below, thereby to minimize the amount of signal delay in the gate electrode and wiring. This makes it possible to sufficiently utilize the merit of high speed operation owing to miniaturization.

In addition, the SAC structure can be formed easily because no formation process such as salicide method is employed. Referring to FIG. 12, before the conductive silicon film 3, barrier film 5 and metal film 6 are formed into the gate electrode and wiring, an insulating film (not shown) is further formed on the metal film 6 and then shaped into a gate electrode and wiring by using photolithography and etching techniques. This results in the gate electrode and wiring having the insulating film on the upper surface thereof. Subsequently, the usual side wall formation process is carried out to obtain the SAC structure.

The reason why the barrier film 5 is used in the polymetal gate electrode structure is as follows.

In the case of a simple two-layer stacked structure such as of metal/conductive silicon, when it passes through a high temperature process inherent in the process of manufacturing a semiconductor device, metal and silicon diffuse mutually to form a silicide layer at the interface therebetween. The resistance value of the silicide layer is usually higher than that of metal, thus leading to an increased resistance value of the gate electrode and wiring.

In order to avoid such a silicide layer formation phenomenon, the barrier layer is provided. When W is used for the metal film 6 in FIG. 12, the above-mentioned WNₓ film or WSiN film suppresses the mutual diffusion of metal and silicon, and functions as the barrier film 5. Since the barrier film 5 avoids formation of a silicide layer, the resistance value of the gate electrode and wiring can be maintained low even after passing through the high temperature process.

However, the polymetal gate electrode employing a WNₓ film or WSiN film as a barrier film, has the following drawback that the resistance value between metal and conductive silicon cannot be minimized and the resistance value between metal and conductive silicon is not stable to the current density variation. This will be described by referring to FIG. 13. As used herein, the term “the resistance value between metal and conductive silicon” is a value obtained by dividing the potential difference between the conductive silicon film 3 and metal film 6 by the current density passing therethrough.

FIG. 13 is a graph showing the result of measurement of the resistance-current density characteristic between metal and conductive silicon in the polymetal gate electrode of FIG. 12. In FIG. 13, the ordinate represents resistance Rc and the abscissa represents current density J.

As shown in FIG. 13, the resistance value between metal and conductive silicon is approximately 1×10⁻⁵ Ω·cm² or more, which cannot be said to be sufficiently low value. This has made it difficult to suppress signal delay due to the resistance between metal and conductive silicon.

Further, as shown in FIG. 13, with respect to the current density variation, the resistance value between metal and conductive silicon is unstable and exhibits non-ohmic property. Thus, the gate voltage varies as the current density varies. This has made it difficult to say that the polymetal gate electrode employing a WNₓ film or WSiN film as a barrier film is suited as a gate electrode.

The foregoing drawbacks seem to be due to high resistance of the WNₓ film or WSiN film as being a barrier film.

### SUMMARY OF THE INVENTION

According to a first aspect of the invention, a semiconductor device comprises: a substrate; a conductive silicon film disposed on the substrate; a silicide film containing metal atoms and silicon atoms disposed on the conductive silicon film; a barrier film containing metal atoms, nitrogen atoms and silicon atoms disposed on the silicide film; and a metal film disposed on the barrier film.

According to a second aspect of the invention, a method for manufacturing a semiconductor device comprises the steps of: (a) forming a conductive silicon film on a substrate; (b) forming a silicide film containing metal atoms and silicon atoms on the conductive silicon film; (c) forming a metal nitride film containing metal atoms and nitrogen atoms on the silicide film; (d) forming a metal film on the metal nitride film; (e) patterning the conductive silicon film, the silicide film, the metal nitride film and the metal film by using photolithography and etching techniques; and (f) performing heat treatment such that the silicon atoms contained in the silicide film is reacted with the metal nitride film, thereby to form a barrier film containing metal atoms, nitrogen atoms and silicon atoms.

According to a third aspect of the invention, a method for manufacturing a semiconductor device comprises the steps of: (a) forming a conductive silicon film on a substrate; (b) forming a silicide film containing metal atoms and silicon atoms on the conductive silicon film; (c) forming a metal nitride film containing metal atoms and nitrogen atoms on the silicide film; (d) forming a metal film on the metal nitride film; (e) performing heat treatment such that the silicon atoms contained in the silicide film is reacted with the metal nitride film, thereby to form a barrier film containing metal atoms, nitrogen atoms and silicon atoms; and (f) patterning the conductive silicon film, the silicide film, the barrier film and the metal film by using photolithography and etching technologies.

The first aspect can realize the semiconductor device comprising the polymetal gate electrode exhibiting low resistance property and ohmic property because the silicide film is interposed between the conductive silicon film and barrier film.

With the method of the second aspect, it is able to manufacture the semiconductor device of the first aspect. Further, an extremely thin barrier film can be obtained because it is formed by using thermal reaction between the silicide film and metal nitride film, thereby effectively suppressing the resistance value between metal and conductive silicon.

The method of the third aspect has the same effect as the method of the second aspect.

It is an object of the present invention to provide a semiconductor device comprising a polymetal gate electrode that can prevent formation of a silicide layer at the interface between metal and conductive silicon and also exhibit low resistance property and ohmic property, as well as a method for manufacturing the same.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram illustrating a semiconductor device according to a first preferred embodiment of the invention;

FIG. 2 is a diagram showing the resistance-current density characteristic between metal and conductive silicon in the semiconductor device of the first preferred embodiment;

FIGS. 3 to 9 are diagrams illustrating a sequence of steps in a method for manufacturing a semiconductor device according to a second preferred embodiment;

FIGS. 10 and 11 are diagrams illustrating a sequence of steps in a method for manufacturing a semiconductor device according to a third preferred embodiment;

FIG. 12 is a diagram illustrating a conventional semiconductor device; and

FIG. 13 is a diagram showing the resistance-current density characteristic between metal and conductive silicon in a conventional semiconductor device.

### DESCRIPTION OF THE PREFERRED EMBODIMENTS

First Preferred Embodiment

A first preferred embodiment of the invention is directed to realize a semiconductor device comprising a polymetal gate electrode that can prevent formation of a silicide layer at the interface between metal and conductive silicon and also exhibit low resistance property and ohmic property. This semiconductor device can overcome the aforesaid drawbacks by interposing a silicide film between a conductive silicon film and a barrier film.

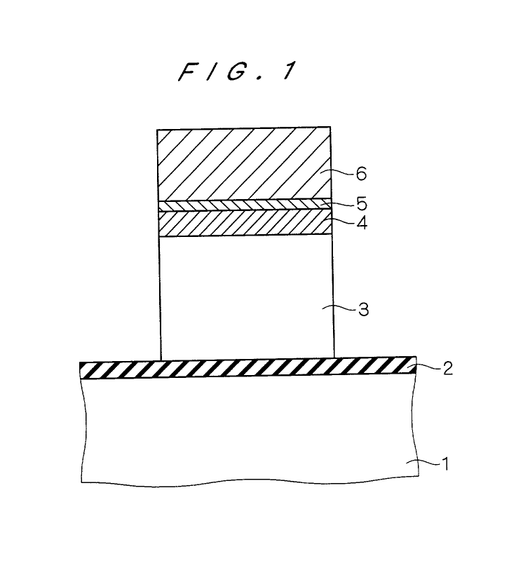

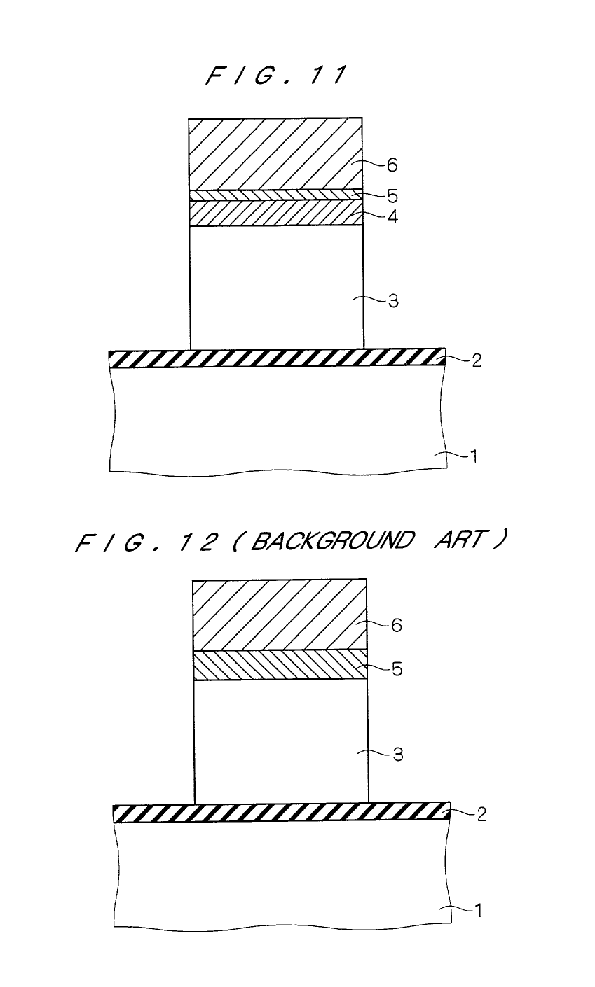

FIG. 1 is a cross section illustrating a semiconductor device according to the first preferred embodiment. As shown in FIG. 1, in this semiconductor device, a polymetal electrode is formed via a gate insulting film 2 (e.g., oxide film) on a semiconductor substrate 1 (e.g., silicon substrate) in a similar manner to that in FIG. 12.

This polymetal gate electrode is however different from that of FIG. 12, in that a conductive silicon film 3, silicide film 4, barrier film 5 and metal film 6 are stacked over the semiconductor substrate 1 in the order named. That is, unlike FIG. 12, the silicide film 4 is interposed between the conductive silicon film 3 and barrier film 5.

For instance, a poly-Si film and a W film may be adopted for the conductive silicon film 3 and metal film 6, respectively. The silicide film 4 is a film containing metal atoms and silicon atoms, and a WSi film may be adopted therefor. The barrier film 5 is a film containing metal atoms, nitrogen atoms and silicon atoms, and a WSiN film may be adopted therefor.

By providing the silicide film 4, the high resistance property of the barrier film 5 is relaxed and the resistance value between metal and conductive silicon can be lowered than the conventional technique.

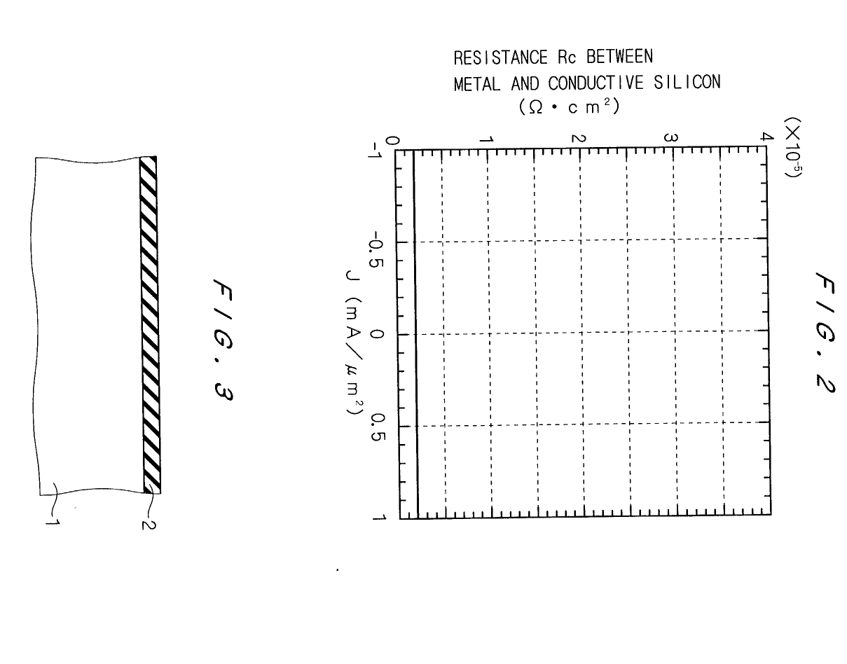

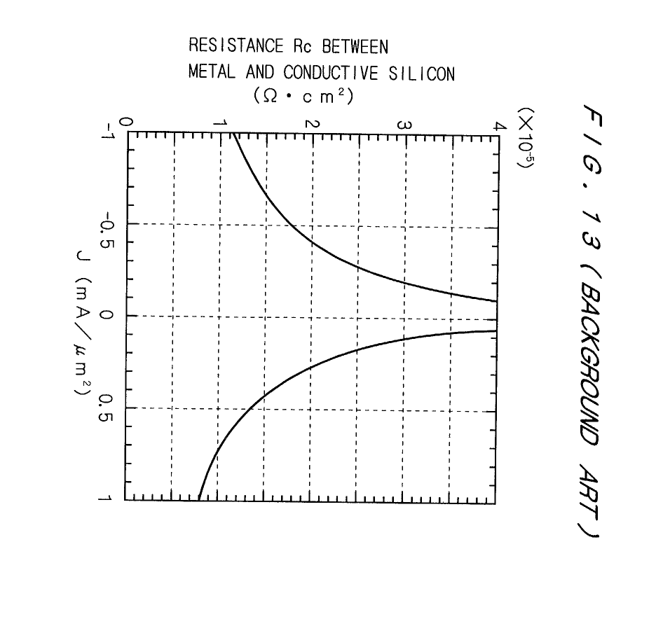

This structure is subjected to the same measurement of the resistance-current density characteristic between metal and conductive silicon as that in FIG. 13, and the result is given in FIG. 2. As shown in FIG. 2, in the semiconductor device of this embodiment the resistance value between metal and conductive silicon is approximately 2×10⁻⁶ Ω·cm² or below, which is sufficiently lower than that of the conventional semiconductor device. Accordingly, signal delay due to resistance between metal and conductive silicon can be suppressed by using the semiconductor device of this embodiment.

Further, as shown in FIG. 2, the resistance value between metal and conductive silicon remains constant irrespective of the current density value, and the semiconductor device of this embodiment exhibits ohmic property. Therefore, the gate voltage is hard to vary relative to the current density variation.

Thus, in the semiconductor device of this embodiment, the semiconductor device comprising the polymetal gate electrode exhibiting low resistance property and ohmic property can be realized by interposing the silicide film 4 between the conductive silicon film 3 and barrier film 5.

The metal atoms contained in the silicide film 4 and barrier film 5 may be one or more kinds selected from the group consisting of W, Mo, Ti, Ta, Nb, V, Zr, Hf, Cr and Co. In any case, the same effect as above described is obtainable.

Second Preferred Embodiment

A second preferred embodiment relates to a method for manufacturing a semiconductor device according to the first preferred embodiment, which is described by referring to FIGS. 3 to 9.

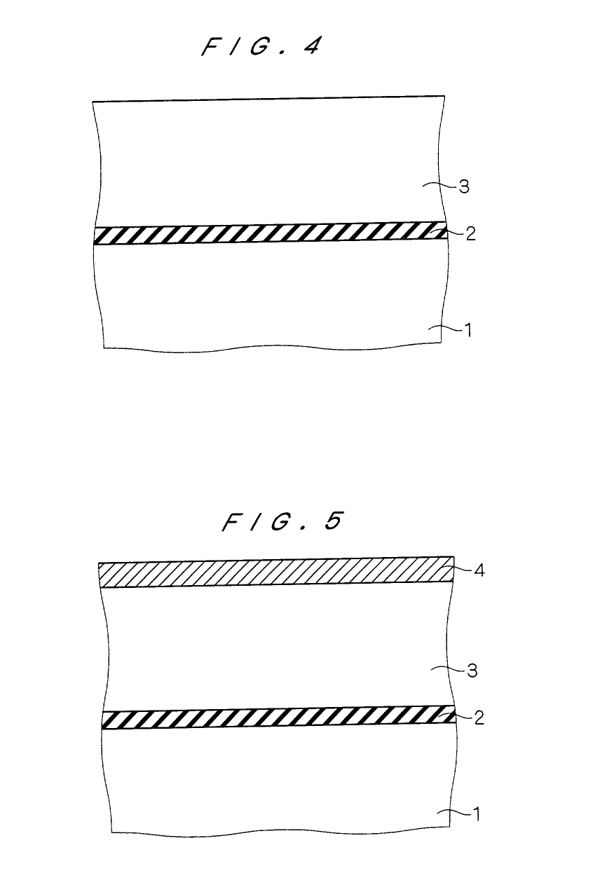

Firstly, as shown in FIG. 3, on a semiconductor substrate 1 such as a silicon substrate, a gate insulating film 2 such as an oxide film is formed in a thickness of approximately 3 nm by means such as thermal oxidation. Subsequently, as shown in FIG. 4, a conductive silicon film 3 such as a poly-Si film is formed in a thickness of approximately 100 nm on the gate insulating film 2 by means such as CVD (chemical vapor deposition).

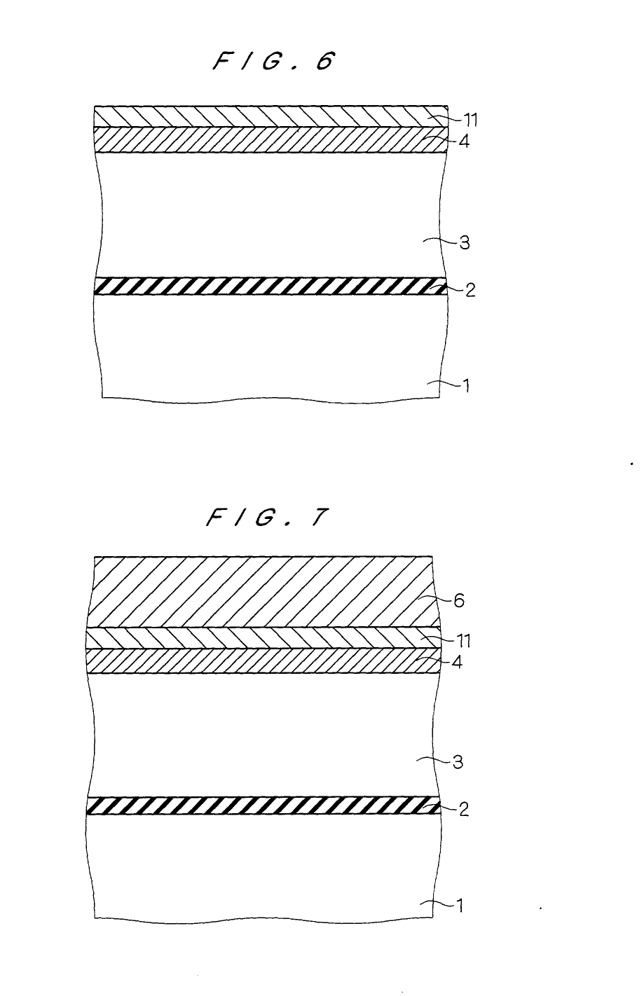

Then, as shown in FIG. 5, a silicide film 4 such as a WSi film is formed in a thickness of approximately 6 nm on the conductive silicon film 3 by means such as sputtering. As shown in FIG. 6, a metal nitride film 11 such as a WN film is formed in a thickness of approximately 5 nm on the silicide film 4 by means such as sputtering. As shown in FIG. 7, a metal film 6 such as a W film is formed in a thickness of approximately 40 nm on the metal nitride film 11 by means such as sputtering.

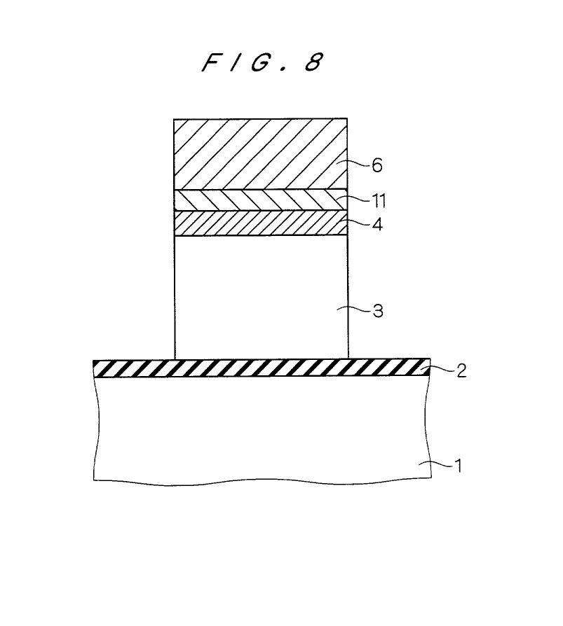

As shown in FIG. 8, the conductive silicon film 3, silicide film 4, metal nitride film 11 and metal film 6 are patterned into the shape of a polymetal gate electrode by using photolithography and etching techniques.

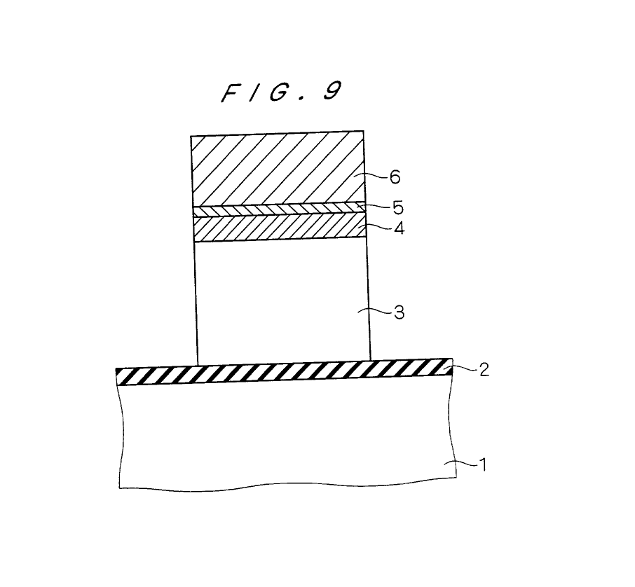

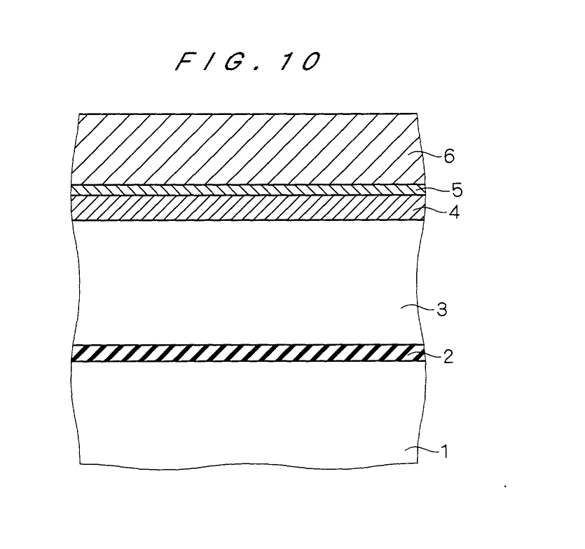

Subsequently, for instance, heat treatment of about 950° C. is performed such that the metal nitride film 11 is reacted with the silicon atoms in the silicide film 4 disposed immediately therebelow. The result is that as shown in FIG. 9, a barrier film 5 containing metal atoms, nitrogen atoms and silicon atoms is formed in a thickness of approximately 1.5 nm in the vicinity of the interface between the metal nitride film 11 and silicide film 4. The barrier film 5 is, for example, a WSiN film.

Note that a WN film has a low stability to heat and, upon heat treatment, N component is separated and the WN film is easily transformed into a W film. Therefore, when the WN film is used for the metal nitride film 11, the area of the metal nitride film 11 except for the portion to be transformed into the barrier film 5 due to the heat treatment, becomes a W film which is then assimilated into the metal film 6 disposed thereon.

For instance, the above heat treatment may be one which is employed in the step of forming source/drain regions of a MISFET.

With the method of the second preferred embodiment, it is able to manufacture a semiconductor device according to the first preferred embodiment. In addition, since the barrier film 5 is formed by using thermal reaction between the silicide film 4 and metal nitride film 11, it is able to form an extremely thin barrier film 5, thereby making it possible to effectively suppress the resistance value between metal and conductive silicon.

Third Preferred Embodiment

A third preferred embodiment is a modification of the method of the second preferred embodiment. In a method of the third preferred method, before the polymetal gate electrode is patterned, a barrier film 5 is formed in the vicinity of the interface between the metal nitride film 11 and silicide film 4.

In the same manner as in the second preferred embodiment, the structure shown in FIG. 7 is obtained.

Subsequently, for instance, heat treatment of about 950° C. is performed such that the metal nitride film 11 is reacted with the silicon atoms in the silicide film 4 disposed immediately therebelow. The result is that as shown in FIG. 10, a barrier film 5 containing metal atoms, nitrogen atoms and silicon atoms is formed in a thickness of approximately 1.5 nm in the vicinity of the interface between the metal nitride film 11 and silicide film 4. The barrier film 5 is, for example, a WSiN film. When a WN film is used for the metal nitride film 11, the area of the metal nitride film 11 except for the portion to be transformed into the barrier film 5 due to the heat treatment, becomes a W film which is then assimilated into the metal film 6 disposed thereon.

Then, as shown in FIG. 11, the conductive silicon film 3, silicide film 4, barrier film 5 and metal film 6 are patterned into the shape of a polymetal gate electrode by using photolithography and etching techniques.

The method of the third preferred embodiment has the same effect as the method of the second preferred embodiment.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a substrate;
a conductive silicon film disposed on said substrate;
a silicide film containing metal atoms and silicon atoms disposed on said conductive silicon film;
a barrier film containing metal atoms, nitrogen atoms and silicon atoms disposed on said silicide film; and
a metal film disposed on said barrier film.

2. The semiconductor device according to claim 1 wherein
said metal atoms contained in said silicide film is one or more kinds selected from the group consisting of W, Mo, Ti, Ta, Nb, V, Zr, Hf, Cr and Co.

3. The semiconductor device according to claim 1 wherein
said metal atoms contained in said barrier film is one or more kinds selected from the group consisting of W, Mo, Ti, Ta, Nb, V, Zr, Hf, Cr and Co.

4. A method for manufacturing a semiconductor device comprising t he steps of:
(a) forming a conductive silicon film on a substrate;
(b) forming a silicide film containing metal atoms and silicon atoms on said conductive silicon film;
(c) forming a metal nitride film containing metal atoms and nitrogen atoms on said silicide film;
(d) forming a metal film on said metal nitride film;
(e) patterning said conductive silicon film, said silicide film, said metal nitride film and said metal film by using photolithography and etching techniques; and
(f) performing heat treatment such that said silicon atoms contained in said suicide film is reacted with said metal nitride film, thereby to form a barrier film containing metal atoms, nitrogen atoms and silicon atoms.

5. The method according to claim 4 wherein
said metal atoms contained in said silicide film is one or more kinds selected from the group consisting of W, Mo, Ti, Ta, Nb, V, Zr, Hf, Cr and Co.

6. The method according to claim 4 wherein
said metal atoms contained in said barrier film is one or more kinds selected from the group consisting of W, Mo, Ti, Ta, Nb, V, Zr, Hf, Cr and Co.

7. A method for manufacturing a semiconductor device comprising the steps of:
(a) forming a conductive silicon film on a substrate;
(b) forming a silicide film containing metal atoms and silicon atoms on said conductive silicon film;
(c) forming a metal nitride film containing metal atoms and nitrogen atoms on said silicide film;
(d) forming a metal film on said metal nitride film;
(e) performing heat treatment such that said silicon atoms contained in said silicide film is reacted with said metal nitride film, thereby to form a barrier film containing metal atoms, nitrogen atoms and silicon atoms; and
(f) patterning said conductive silicon film, said silicide film, said barrier film and said metal film by using photolithography and etching techniques.

8. The method according to claim 7 wherein
said metal atoms contained in said silicide film is one or more kinds selected from the group consisting of W, Mo, Ti, Ta, Nb, V, Zr, Hf, Cr and Co.

9. The method according to claim 7 wherein
said metal atoms contained in said barrier film is one or more kinds selected from the group consisting of W, Mo, Ti, Ta, Nb, V, Zr, Hf, Cr and Co.
